(19) United States
(12) Patent Application Publication
(10) Pub. No.: US 2025/0056840 A1
(43) Pub. Date: Feb. 13, 2025

(54) SEMICONDUCTOR DEVICE AND METHOD FOR FORMING THE SAME

(71) Applicant: Taiwan Semiconductor Manufacturing Company, Ltd., Hsinchu (TW)

(72) Inventor: Yen CHUANG, Hsinchu County (TW)

(73) Assignee: Taiwan Semiconductor Manufacturing Company, Ltd., Hsinchu (TW)

(21) Appl. No.: 18/366,937

(22) Filed: Aug. 8, 2023

(51) Int. Cl. H01L 29/423; H01L 21/8238; H01L 27/092; H01L 29/06; H01L 29/08; H01L 29/66; H01L 29/775

(52) U.S. Cl. CPC H01L 29/42392; H01L 21/823814; H01L 27/092; H01L 29/0673; H01L 29/0847; H01L 29/66439; H01L 29/66545; H01L 29/775

(57) ABSTRACT

A semiconductor device includes a substrate. Semiconductor channel layers are over the substrate. A gate structure wraps around each of the semiconductor channel layers. Source/drain epitaxial structures are on opposite sides of the gate structure. Epitaxial seed layers are below the source/drain epitaxial structures, respectively, in which a lattice constant of the epitaxial seed layers is different from a lattice constant of the source/drain epitaxial structures. Isolation layers are over the substrate and vertically below the epitaxial seed layers, respectively.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 10 illustrate a method in various stages of forming a semiconductor device in accordance with some embodiments of the present disclosure.

FIG. 11 is a cross-sectional view of a semiconductor device in accordance with some embodiments of the present disclosure.

FIGS. 12A and 12B are cross-sectional views of a semiconductor device in accordance with some embodiments of the present disclosure.

FIG. 13 is a cross-sectional view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Although embodiments of the present disclosure is explained with respect to a GAA structure, embodiments of the disclosure may also be applied, however, to a variety of metal oxide semiconductor transistors (e.g., complementary-field effect transistor (CFET) and fin field effect transistor (FinFET)).

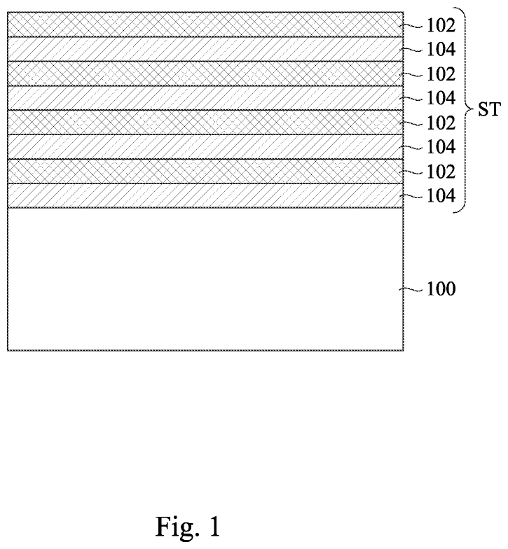

FIGS. 1 to 10 illustrate a method in various stages of forming a semiconductor device in accordance with some embodiments of the present disclosure. Although FIGS. 1 to 10 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂. Ga₂O₃, and the like) or combinations thereof. The semiconductor materials may be doped or undoped. Other substrates that may be used include multi-layered substrates, gradient substrates, or hybrid orientation substrates. In some embodiments, the substrate 100 may include a (100) crystalline orientation or a (110) crystalline orientation.

A semiconductor stack ST is formed over the substrate 100. The semiconductor stack ST includes alternating semiconductor layers 102 and 104. In some embodiments, the semiconductor layers 102 may be made of pure silicon layers that are free of germanium. The semiconductor layers 102 may also be substantially pure silicon layers, for example, with a germanium percentage lower than about 1 percent. The semiconductor layers 104 may be made of silicon germanium. For example, the germanium percentage (atomic percentage concentration) of the semiconductor layers 104 is in a range from about 15 percent and about 40 percent. In some embodiments, the semiconductor layers 102 and 104 may be deposited using suitable deposition process, such as selective epitaxial growth (SEG), chemical vapor deposition (CVD), molecular beam epitaxy (MBE), or other suitable process(es). In some embodiments, the semiconductor layers 104 may be removed during a replacement gate (RPG) process, and thus the semiconductor layers 104 can also be referred to as sacrificial layers. In some embodiments, the semiconductor layers 102 may serve as channel regions of a transistor, and thus the semiconductor layers 102 can also be referred to as semiconductor channel layers. In some embodiments, the semiconductor stack ST is patterned to form a fin-like structure that protrudes from a top surface of the substrate 100, and thus the semiconductor stack ST may also be referred to as a fin structure.

In some embodiments, the semiconductor layers 102 can be interchangeably referred to as nanosheets, nanowires, nanoslabs, nanorings, or nanostructures having nano-scale size (e.g., a few nanometers), depending on their geometry. It is understood that the number of the semiconductor layers 102 is merely used to explain, and the present disclosure is not limited thereto. In some embodiments, the number of the semiconductor layers 102 is in a range from about 1 to 10.

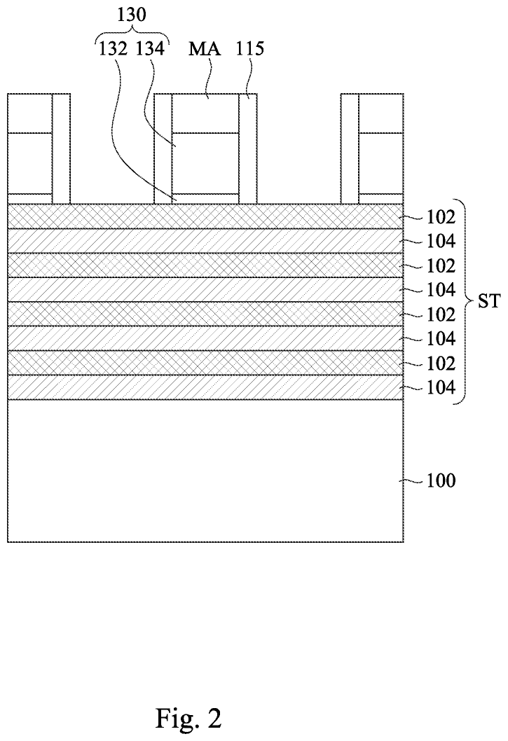

Reference is made to FIG. 2. Dummy gate structures 130 are formed over the substrate 100 and crossing the semiconductor stack ST. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA over the dummy gate layer, and then performing an etching process to the dummy dielectric layer and the dummy gate layer by using the patterned masks MA as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation. In some embodiments, each of the patterned masks MA includes silicon nitride, silicon oxide, combinations thereof, or the like.

Gate spacers 115 are formed on opposite sidewalls of each of the dummy gate structures 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like.

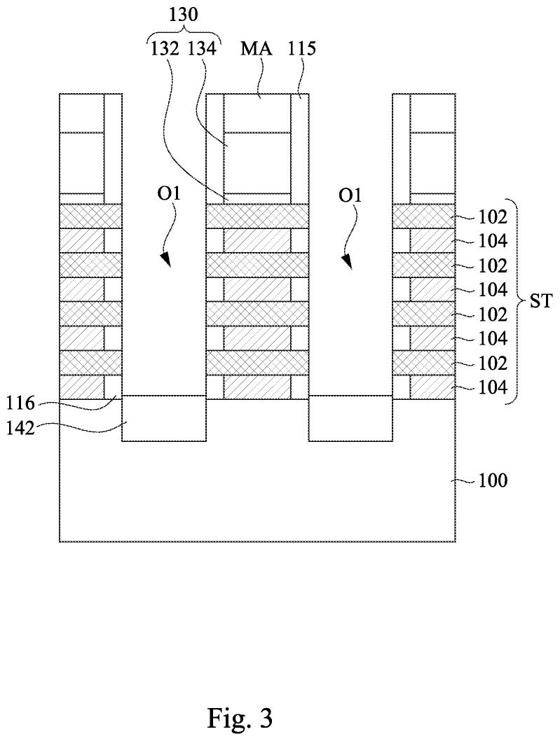

Reference is made to FIG. 3. An etching process is performed to remove portions of the semiconductor stack ST by using the dummy gate structures 130 and the gate spacers 115 as etch mask, so as to form source/drain openings O1 in the semiconductor stack ST. In some embodiments, the etching process may be wet etch, dry etch, or combinations thereof. In some embodiments, bottommost ends of the source/drain openings O1 may be lower than top surface of the substrate 100.

After the source/drain openings O1 are formed, the semiconductor layers 104 are laterally etched to form sidewall recesses. In some embodiments, the sidewalls of the semiconductor layers 104 may be etched using isotropic etching processes, such as wet etching or the like. In some embodiments where the semiconductor layers 104 include, e.g., SiGe, and the semiconductor layers 102 include, e.g., Si, an etch process with tetramethylammonium hydroxide (TMAH), ammonium hydroxide (NH₄OH), or the like may be used to etch sidewalls of the semiconductor layers 104.

Then, inner spacers 116 are formed in the sidewall recesses on opposite ends of each of the semiconductor layers 104. In some embodiments, the inner spacers 116 may be formed by, for example, depositing an inner spacer layer blanket over the substrate 100 and filling the sidewall recesses, and then performing an anisotropic etching to remove portions of the inner spacer layer outside the sidewall recesses, leaving the remaining portions of the inner spacer layer in the sidewall recesses as the inner spacers 116. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

Epitaxial layers 142 are formed at bottoms of the source/drain openings O1. The epitaxial layers 142 may be made of silicon (Si). In some embodiments, the formation of the epitaxial layers 142 may include a plurality of deposition cycles, in which each deposition cycle may include a selective epitaxial growth (SEG) process and an etching process. In some embodiments, the SEG process may selectively grow a semiconductor material on exposed semiconductor surfaces, such as the exposed surfaces of the substrate 100 and the exposed surfaces of the semiconductor layers 102. However, because the exposed areas of the substrate 100 are greater than the exposed area of each of the semiconductor layers 102, the semiconductor material may include higher growing rate on the exposed areas of the substrate 100 than on the exposed area of each of the semiconductor layers 102. That is, a greater amount of the semiconductor material will be grown on the exposed areas of the substrate 100 than on the exposed area of each of the semiconductor layers 102. As a result, the etching process in each deposition cycle of the epitaxial layers 142 may remove portions of the semiconductor material formed on the exposed area of each of the semiconductor layers 102, while portions of the semiconductor material may remain over the substrate 100 after the etching process. Accordingly, performing several deposition cycles may allow a bottom-up deposition for the epitaxial layers 142. That is, the epitaxial layers 142 may be formed from the bottoms of the source/drain openings O1 via a bottom-up manner. In some embodiments, the epitaxial layers 142 may be formed without performing an implantation process, and thus the epitaxial layers 142 are un-doped.

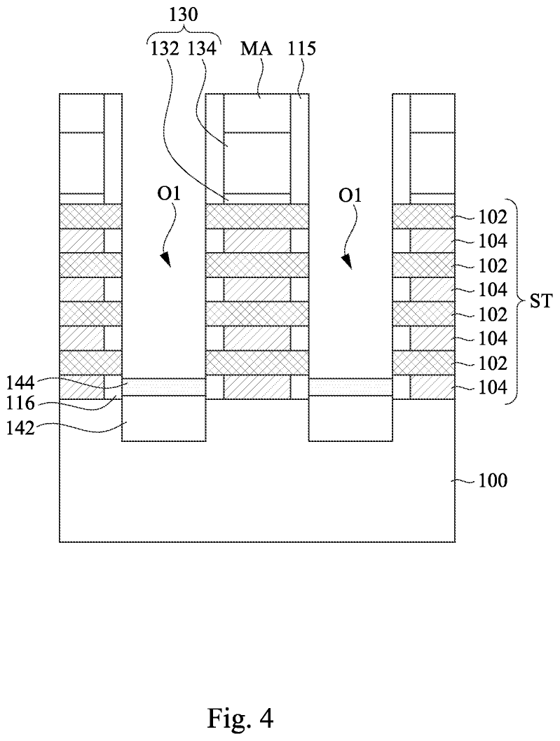

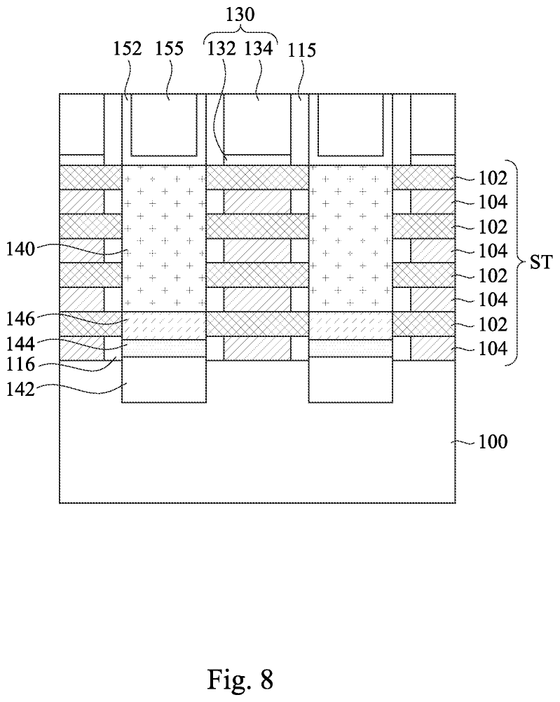

Reference is made to FIG. 4. Isolation layers 144 are formed in the source/drain openings O1 and over the respective epitaxial layers 142. In some embodiments, the isolation layers 144 may be made of dielectric material, such as silicon nitride (SiNₓ), silicon oxide (SiOₓ), silicon oxynitride (SiOₓN_{y}), aluminum oxide (Al₂O₃), or the like. In some embodiments, the isolation layers 144 may be formed by suitable deposition process and etching process. The isolation layers 144 may be in contact with the bottommost inner spacers 116 that are vertically between the substrate 100 and the bottommost semiconductor layer 102, while other inner spacers 116 above the bottommost inner spacers 116 may be free of coverage by the isolation layers 144. The isolation layers 144 provide electrical isolation between the overlaying source/drain structures (e.g., epitaxial seed layers 146 and source/drain epitaxial structures 140 in FIG. 8) and the substrate 100.

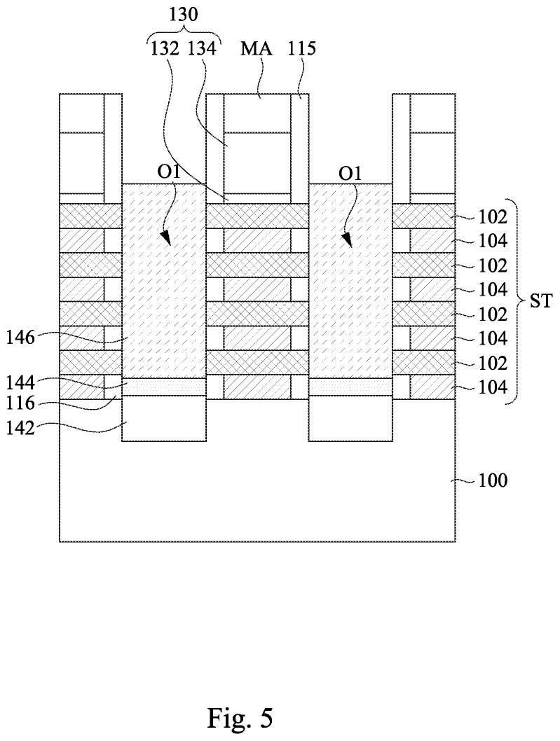

Reference is made to FIG. 5. Epitaxial seed layers 146 are formed in the source/drain openings O1 and over the respective isolation layers 144. In some embodiments, the epitaxial seed layers 146 may include crystalline structure. For example, the epitaxial seed layers 146 may be made of silicon or silicon germanium. In the embodiments where the device is an N-type device (NMOS), the epitaxial seed layers 146 may be made of substantially pure silicon, for example, with a germanium percentage lower than about 1 percent. In the embodiments where the device is a P-type device (PMOS), the epitaxial seed layers 146 may be made of silicon germanium (Si₁₋ₓGeₓ), with germanium concentration in a range from about 0% to 50% (x=0%˜50%). The epitaxial seed layers 146 may be N-type doped (for N-type device), P-type doped (for P-type device) or undoped, and the dopant concentration may be in a range from about 10¹⁷ atoms/cm³ to about 10²¹ atoms/cm³. Exemplary N-type dopants may be phosphorus (P), arsenic (As), or antimony (Sb), or the like. Exemplary P-type dopants may be boron (B), gallium (Ga), indium (In), aluminium (Al), or the like. The epitaxial seed layers 146 may be in-situ doped or may be ex-situ doped. In some embodiments, the epitaxial seed layers 146 and the epitaxial layers 142 may be made of a same material, such as silicon.

The epitaxial seed layers 146 may be deposited using suitable deposition process, such as selective epitaxial growth (SEG) process. In some embodiments, the epitaxial seed layers 146 may be deposited using silicon-containing precursor (silicon source) and/or germanium-containing precursor (germanium source). Exemplary silicon-containing precursor may include SiH₄, Si₂H₆, SiₓH₂ₓ₊₂, H₂SiCl₂, or the like. Exemplary silicon-containing precursor may include GeH₄, Ge₂H₆, or the like. The deposition process is performed under a temperature in a range from about 300° C. to about 900° C. The deposition process is performed under a pressure in a range from about 0.1 torr to about 300 torr.

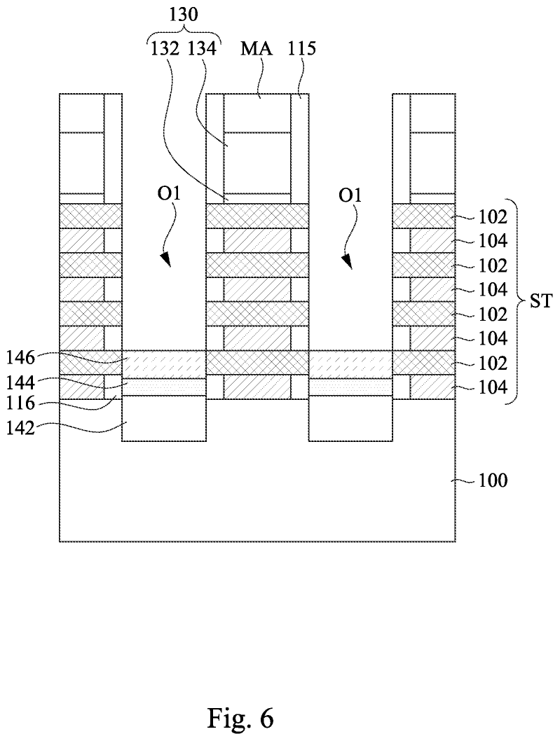

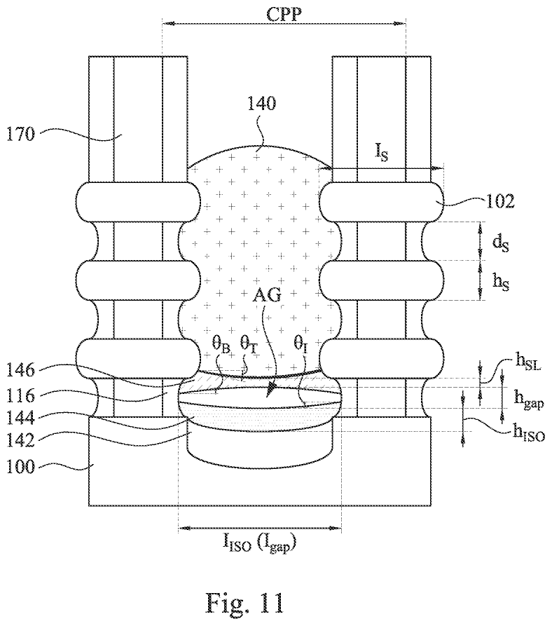

Reference is made to FIG. 6. An etching back process is performed to lower top surfaces of the epitaxial seed layers 146 to a desired position. In the depicted embodiments, top surfaces of the etched epitaxial seed layers 146 may be substantially level with top surfaces of the bottommost one of the semiconductor layers 102. In other embodiments, top surfaces of the etched epitaxial seed layers 146 may be lower than top surfaces of the bottommost one of the semiconductor layers 102 (see embodiments of FIG. 11).

The etching back process may be wet etch, dry etch, or the like. In some embodiments, the etching back process may include reactive-ion etching (RIE). The RIE etching may be performed using etchant such as Cl, HCl, BCl₃, SF₆, CF₄, C₄F₈, Ar, or the like. The RIE etching may be performed under a pressure in a range from about 0.01 torr to about 100 torr, or a pressure in a range from about 0.1 mtorr to about 100 mtorr.

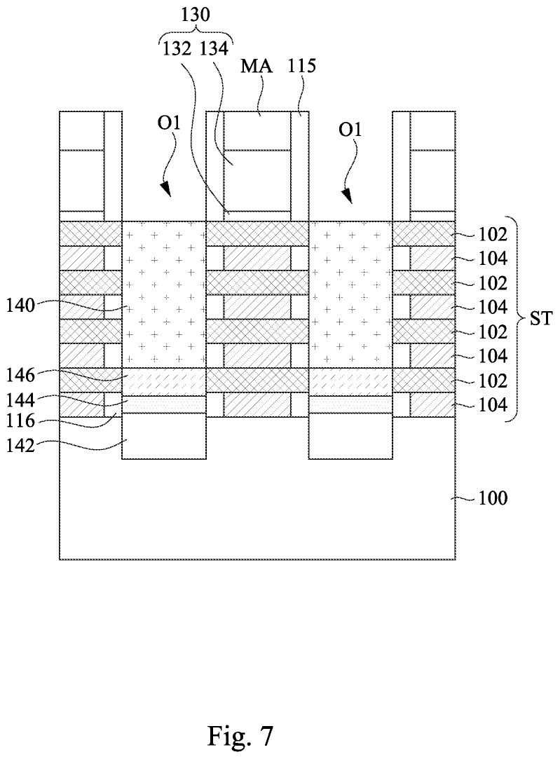

Reference is made to FIG. 7. Source/drain epitaxial structures 140 are formed in the source/drain openings O1 and over the respective epitaxial seed layers 146. The source/drain epitaxial structures 140 may be formed by suitable deposition process, such as a selective epitaxial growth (SEG) process. In some embodiments, the SEG process may selectively grow a semiconductor material on exposed semiconductor surfaces, such as the exposed surfaces of the epitaxial seed layers 146 and the exposed surfaces of the semiconductor layers 102. In some embodiments, an implantation process may be performed to the source/drain epitaxial structures 140. For example, when the device is an N-type device, the source/drain epitaxial structures 140 may be doped with n-type dopants, such as phosphorus (P), arsenic (As), or antimony (Sb), or the like. Alternatively, when the device is a P-type device, the source/drain epitaxial structures 140 may be doped with p-type dopants, such as boron (B), gallium (Ga), indium (In), aluminium (Al), or the like. In some embodiments, source/drain epitaxial structures 140 may include different material than the epitaxial seed layers 146. For example, the epitaxial seed layers 146 may be made of silicon, while the source/drain epitaxial structures 140 may be made of silicon germanium. That is, the source/drain epitaxial structures 140 include higher germanium concentration than the epitaxial seed layers 146. In some embodiments, the dopant concentration of the source/drain epitaxial structures 140 may be higher than the dopant concentration of the epitaxial seed layers 146. For example, the dopant concentration of the source/drain epitaxial structures 140 is in a range from about 1×10¹⁷ atoms/cm³ to about 1×10²² atoms/cm³.

In some embodiments, material of the source/drain epitaxial structures 140 has a different lattice constant than material of the epitaxial seed layers 146, such that strain may be created in the source/drain epitaxial structures 140. For example, the source/drain epitaxial structures 140 may be a strained silicon germanium (SiGe) layer. Generally, a strain is created when a first semiconductor material is grown onto a single-crystal of a second semiconductor material when the two semiconductor materials are lattice-mismatched to each other. Silicon and silicon germanium are lattice-mismatched to each other such that the growth of one of them onto the other produces a strain which can be either tensile or compressive. In the depicted embodiments, silicon germanium (e.g., source/drain epitaxial structures 140) is epitaxially grown on silicon (e.g., epitaxial seed layers 146) having a crystal structure aligned with the silicon crystal structure. Because silicon germanium normally has a larger crystal structure than silicon, the epitaxially grown silicon germanium becomes internally compressed. As a result, the source/drain epitaxial structures 140 are strained, which in turn will improve the device performance. In some embodiments where the epitaxial seed layers 146 are omitted, the underlying isolation layers 144 may not create strain to the source/drain epitaxial structures 140.

Reference is made to FIG. 8. A contact etch stop layer (CESL) 155 is formed covering the source/drain epitaxial structures 140. Afterwards, an interlayer dielectric (ILD) layer 152 is formed over the CESL 155. Then, a planarization process, such as CMP, is performed to remove excess materials of the CESL 155 and ILD layer 152, such that top surfaces of the dummy gate structures 130 are exposed.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

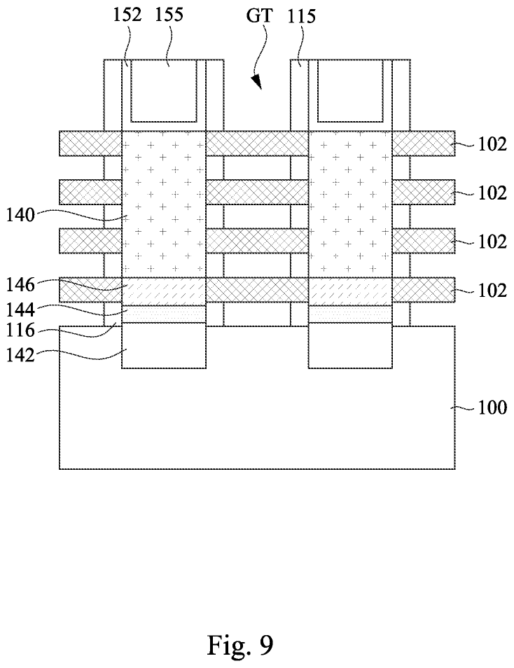

Reference is made to FIG. 9. The dummy gate structures 130 are removed to form gate trenches GT between each pair of the gate spacers 115. Then, an etching process is performed to remove the semiconductor layers 104 through the gate trenches GT, such that that the semiconductor layers 102 are suspended over the substrate 100. In some embodiments, the dummy gate structures 130 and the semiconductor layers 102 may be removed using suitable etching process, such as dry etch, wet etch, or the like.

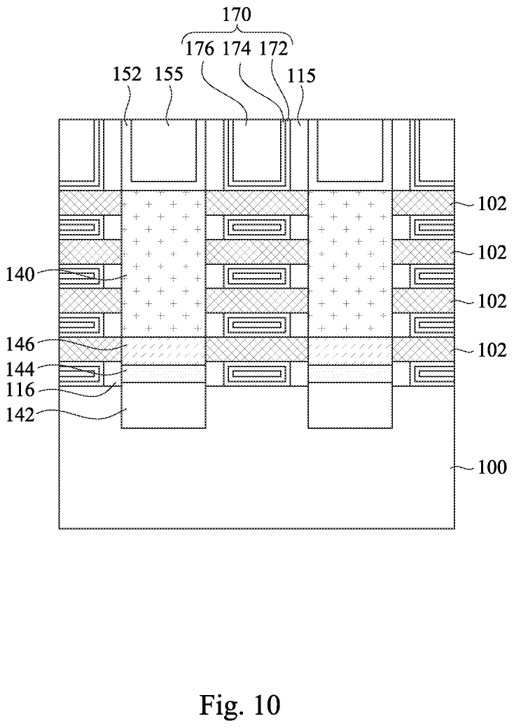

Reference is made to FIG. 10. Metal gate structures 170 are formed in the gate trenches GT and wrapping around each of the semiconductor layers 102. In some embodiments, each of the metal gate structures 170 includes an interfacial layer (not shown), a gate dielectric layer 172, a work function metal layer 174, and a filling metal 176. Then, a planarization process, such as CMP, is performed to remove excess materials of the gate dielectric layer 172, the work function metal layer 174, and the filling metal 176 until the ILD layer 152 is exposed.

In some embodiments, the interfacial layers may be made of oxide, such as aluminum oxide (Al₂O₃), silicon oxide (SiO₂), or the like. In some embodiments, the gate dielectric layer 172 may include high-k dielectric. Examples of high-k dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof.

The work function metal layer 174 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal 176 may include tungsten (W), aluminum (Al), copper (Cu), or another suitable conductive material(s).

The metal gate structure 170, the source/drain epitaxial structures 140 (and/or the epitaxial seed layers 146, if doped) on opposite sides of the metal gate structure 170, and the semiconductor layers 102 that are in contact with the source/drain epitaxial structures 140 (and/or the epitaxial seed layers 146, if doped) may collectively serve as a transistor.

FIG. 11 is a cross-sectional view of a semiconductor device in accordance with some embodiments of the present disclosure. It is noted that some elements in FIG. 11 are similar to those described with respect to FIGS. 1 to 10, such elements are labeled the same and relevant details will not be repeated for brevity.

As shown in FIG. 11, an air gap AG is formed vertically between the isolation layer 144 and the epitaxial seed layer 146. This is because when the epitaxial seed layer 146 is formed through a selective epitaxial growth (SEG) process, the SEG process may selectively grow a semiconductor material on semiconductor surfaces, such as the exposed surfaces of the semiconductor layers 102. However, the semiconductor material has low growth rate or substantial zero growth rate on dielectric surfaces, such as the exposed surfaces of the isolation layer 144. Accordingly, during forming the epitaxial seed layers 146 as discussed in FIG. 5, the epitaxial seed layers 146 may be grown from the semiconductor layers 102 with a higher growth rate, and the epitaxial seed layers 146 may seal the air gap AG as shown in FIG. 11. The air gap AG between the isolation layer 144 and the epitaxial seed layer 146 may be beneficial for device performance because leakage current and parasitic capacitance can be reduced.

In some embodiments, the epitaxial seed layer 146 may be in contact with bottom portion of sidewall of the bottommost semiconductor layer 102, and the source/drain epitaxial structure 140 may be in contact with top portion of sidewall of the bottommost semiconductor layer 102. That is, all of the semiconductor layers 102 are in contact with the source/drain epitaxial structures 140. This may be beneficial for device performance because the source/drain epitaxial structure 140 may include higher dopant concentration than the epitaxial seed layer 146, and the contact between the source/drain epitaxial structure 140 and the bottommost semiconductor layer 102 may increase the current flowing through the bottommost semiconductor layer 102. In some embodiments, top surface of the epitaxial seed layer 146 is lower than top surface of the bottommost semiconductor layer 102, and bottom surface of the epitaxial seed layer 146 is higher than top surface of the substrate 100.

Reference is made to the semiconductor layer 102. The height h_{S} of the semiconductor layer 102 is in a range from about 2 nm to about 20 nm. The length I_{S} of the semiconductor layer 102 is in a range from about 10 nm to about 200 nm. The distance d_{S} between two adjacent semiconductor layers 102 is in a range from about 2 nm to about 20 nm.

Reference is made to the gate structures 170. The pitch CPP of the gate structures 170 is in a range from about 30 nm to about 90 nm.

Reference is made to the epitaxial seed layer 146. The height h_{SL} of the epitaxial seed layer 146 is in a range from about 1 nm to about 30 nm. The length I_{SL} of the epitaxial seed layer 146 is in a range from about 5 nm to about 75 nm.

In some embodiments, the top surface of the epitaxial seed layer 146 may be a concave surface as shown in FIG. 11. In other embodiments, the top surface of the epitaxial seed layer 146 may be a convex surface or a flat surface. For example, the tangent line at the intersection between top surface of the epitaxial seed layer 146 and the semiconductor layer 102 may form an angle θ_{T} with a horizontal line that is substantially parallel to top surface of the substrate 100. In some embodiments, the angle θ_{T} is in a range from about −70°˜70°.

In some embodiments, the bottom surface of the epitaxial seed layer 146 may be a concave surface as shown in FIG. 11. In other embodiments, the bottom surface of the epitaxial seed layer 146 may be a convex surface or a flat surface. For example, the tangent line at the intersection between bottom surface of the epitaxial seed layer 146 and the semiconductor layer 102 may form an angle θ_{B} with a horizontal line that is substantially parallel to top surface of the substrate 100. In some embodiments, the angle θ_{B} is in a range from about −70°˜70°.

Reference is made to the isolation layer 144. The length I_{Iso} of the isolation layer 144 is in a range from about 5 nm to about 75 nm. The height H_{Iso} of the isolation layer 144 is in a range from about 5 nm to about 30 nm. In some embodiments, the isolation layer 144 may include a portion in the substrate 100, the depth d_{Iso} of the isolation layer 144 in the substrate 100 is in a range from about 0 nm to about 30 nm.

In some embodiments, the top surface of the isolation layer 144 may be a concave surface as shown in FIG. 11. In other embodiments, the top surface of the isolation layer 144 may be a convex surface or a flat surface. For example, the tangent line at the intersection between top surface of the isolation layer 144 and the inner spacer 116 may form an angle θ_{I} with a horizontal line that is substantially parallel to top surface of the substrate 100. In some embodiments, the angle θ_{I} is in a range from about −70°˜70°.

Reference is made to the air gap AG. The height h_{gap} of the air gap AG is in a range from about 0 nm to about 20 nm. The length I_{gap} of the isolation layer 144 is in a range from about 0 nm to about 75 nm.

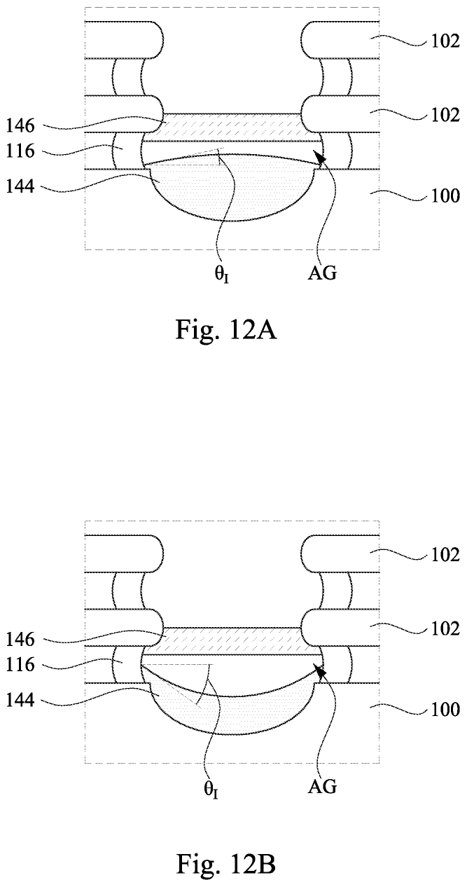

FIGS. 12A and 12B are cross-sectional views of a semiconductor device in accordance with some embodiments of the present disclosure. It is noted that some elements in FIG. 11 are similar to those described with respect to FIGS. 1 to 10, such elements are labeled the same and relevant details will not be repeated for brevity.

In FIG. 12A, the top surface of the isolation layer 144 is a convex surface. That is, the angle θ_{I} is greater than 0°. In FIG. 12B, the top surface of the isolation layer 144 is a concave surface. That is, the angle θ_{I} is less than 0°. In some embodiments, the bottommost inner spacers 116 may be exposed to the air gap AG. That is, an entirety of the isolation layer 144 is vertically separated from the epitaxial seed layer 146 through the air gap AG.

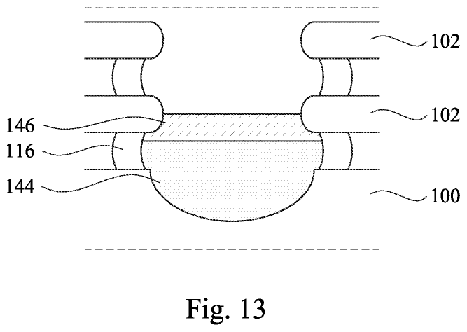

FIG. 13 is a cross-sectional view of a semiconductor device in accordance with some embodiments of the present disclosure. It is noted that some elements in FIG. 11 are similar to those described with respect to FIGS. 1 to 10, such elements are labeled the same and relevant details will not be repeated for brevity. In FIG. 13, the isolation layer 144 is in contact with the epitaxial seed layer 146. That is, no air gap is formed between the isolation layer 144 and the epitaxial seed layer 146.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure include forming an epitaxial seed layer over an isolation layer in source/drain opening. Source/drain epitaxial structure is then formed over the epitaxial seed layer. Due to lattice mismatch between the epitaxial seed layer and the source/drain epitaxial structure, strain is induced in the source/drain epitaxial structure, which in turn will improve the device performance. In some embodiments of the present disclosure, air gap may be formed between the isolation layer and the epitaxial seed layer, the air gap may be beneficial for device performance because leakage current and parasitic capacitance can be reduced.

In some embodiments of the present disclosure, a semiconductor device includes a substrate. Semiconductor channel layers are over the substrate. A gate structure wraps around each of the semiconductor channel layers. Source/drain epitaxial structures are on opposite sides of the gate structure. Epitaxial seed layers are below the source/drain epitaxial structures, respectively, in which a lattice constant of the epitaxial seed layers is different from a lattice constant of the source/drain epitaxial structures.

In some embodiments, one of the epitaxial seed layers and one of the isolation layers both are in contact with a bottommost one of the semiconductor channel layers.

In some embodiments, one of the source/drain epitaxial structures is in contact with all of the semiconductor channel layers.

In some embodiments, the semiconductor device further includes epitaxial layers in the substrate and vertically below the isolation layers, respectively.

In some embodiments, the epitaxial layers and the epitaxial seed layers are made of a same material.

In some embodiments, the semiconductor device further includes isolation layers over the substrate and vertically below the epitaxial seed layers, respectively.

In some embodiments, an air gap is vertically between one of the epitaxial seed layers and one of the isolation layers.

In some embodiments, the semiconductor device further includes an inner spacer in contact with the gate structure and a bottom surface of a bottommost one of the semiconductor channel layers, wherein the inner spacer is exposed to the air gap.

In some embodiments of the present disclosure, a semiconductor device includes a substrate. Semiconductor channel layers are over the substrate. A gate structure wraps around each of the semiconductor channel layers. Source/drain epitaxial structures are on opposite sides of the gate structure. Epitaxial seed layers are below the source/drain epitaxial structures, respectively. Dielectric layers are over the substrate and vertically below the epitaxial seed layers, respectively, in which an air gap is vertically between one of the epitaxial seed layers and one of the dielectric layers.

In some embodiments, the source/drain epitaxial structures have a higher germanium concentration than the epitaxial seed layers.

In some embodiments, the one of the epitaxial seed layers has a concave bottom surface, and the one of the dielectric layers has a concave top surface.

In some embodiments, a top surface of one of the epitaxial seed layers is lower than a top surface of a bottommost one of the semiconductor channel layers.

In some embodiments, the semiconductor device further includes epitaxial layers in the substrate and in contact with bottom surfaces of the dielectric layers, respectively, wherein the epitaxial layers and the epitaxial seed layers are made of a same material.

In some embodiments, an entirety of the one of the epitaxial seed layers is spaced apart from the one of the dielectric layers through the air gap.

In some embodiments, a bottom surface of the epitaxial seed layers is higher than a top surface of the substrate.

In some embodiments of the present disclosure, a method includes forming semiconductor layers one above another over a substrate; performing an etching process to form a source/drain opening in the semiconductor layers and the substrate; forming an epitaxial seed layer in the source/drain opening; forming a source/drain epitaxial structure over the epitaxial seed layer and in contact with the semiconductor layers, wherein the source/drain epitaxial structure and the epitaxial seed layer are made of different materials such that strain is created in the source/drain epitaxial structure; and forming a gate structure over the semiconductor layers.

In some embodiments, forming the epitaxial seed layer comprises depositing an epitaxial material in the source/drain opening; and etching back the epitaxial material to expose sidewalls of the semiconductor layers.

In some embodiments, etching back the epitaxial material is performed until a bottommost one of the semiconductor layers is exposed.

In some embodiments, prior to forming the epitaxial seed layer, the method further comprises forming an epitaxial layer in a bottom portion of the source/drain opening; and forming an isolation layer over the epitaxial layer.

In some embodiments, an air gap is formed vertically between the epitaxial seed layer and the isolation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device,
a substrate;
semiconductor channel layers over the substrate;
a gate structure wrapping around each of the semiconductor channel layers;
source/drain epitaxial structures on opposite sides of the gate structure; and
epitaxial seed layers below the source/drain epitaxial structures, respectively, wherein a lattice constant of the epitaxial seed layers is different from a lattice constant of the source/drain epitaxial structures.

2. The semiconductor device of claim 1, wherein one of the epitaxial seed layers is in contact with a bottommost one of the semiconductor channel layers.

3. The semiconductor device of claim 1, wherein one of the source/drain epitaxial structures is in contact with all of the semiconductor channel layers.

4. The semiconductor device of claim 1, further comprising epitaxial layers in the substrate and below the epitaxial seed layers, respectively, wherein the epitaxial layers are vertically spaced apart from the epitaxial layers.

5. The semiconductor device of claim 4, wherein the epitaxial layers and the epitaxial seed layers are made of a same material.

6. The semiconductor device of claim 1, further comprising isolation layers over the substrate and vertically below the epitaxial seed layers, respectively.

7. The semiconductor device of claim 6, wherein an air gap is vertically between one of the epitaxial seed layers and one of the isolation layers.

8. The semiconductor device of claim 7, further comprising an inner spacer in contact with the gate structure and a bottom surface of a bottommost one of the semiconductor channel layers, wherein the inner spacer is exposed to the air gap.

9. A semiconductor device,
a substrate;
semiconductor channel layers over the substrate;
a gate structure wrapping around each of the semiconductor channel layers;
source/drain epitaxial structures on opposite sides of the gate structure;
epitaxial seed layers below the source/drain epitaxial structures, respectively; and
dielectric layers over the substrate and vertically below the epitaxial seed layers, respectively, wherein an air gap is vertically between one of the epitaxial seed layers and one of the dielectric layers.

10. The semiconductor device of claim 9, wherein the source/drain epitaxial structures have a higher germanium concentration than the epitaxial seed layers.

11. The semiconductor device of claim 9, wherein the one of the epitaxial seed layers has a concave bottom surface, and the one of the dielectric layers has a concave top surface.

12. The semiconductor device of claim 9, wherein a top surface of one of the epitaxial seed layers is lower than a top surface of a bottommost one of the semiconductor channel layers.

13. The semiconductor device of claim 9, further comprising epitaxial layers in the substrate and in contact with bottom surfaces of the dielectric layers, respectively, wherein the epitaxial layers and the epitaxial seed layers are made of a same material.

14. The semiconductor device of claim 9, wherein an entirety of the one of the epitaxial seed layers is spaced apart from the one of the dielectric layers through the air gap.

15. The semiconductor device of claim 9, wherein a bottom surface of the epitaxial seed layers is higher than a top surface of the substrate.

16. A method, comprising:
forming semiconductor layers one above another over a substrate;
performing an etching process to form a source/drain opening in the semiconductor layers and the substrate;
forming an epitaxial seed layer in the source/drain opening;
forming a source/drain epitaxial structure over the epitaxial seed layer and in contact with the semiconductor layers, wherein the source/drain epitaxial structure and the epitaxial seed layer are made of different materials such that strain is created in the source/drain epitaxial structure; and
forming a gate structure over the semiconductor layers.

17. The method of claim 16, wherein forming the epitaxial seed layer comprises:
depositing an epitaxial material in the source/drain opening; and
etching back the epitaxial material to expose sidewalls of the semiconductor layers.

18. The method of claim 17, wherein etching back the epitaxial material is performed until a bottommost one of the semiconductor layers is exposed.

19. The method of claim 16, wherein prior to forming the epitaxial seed layer, the method further comprises:
forming an epitaxial layer in a bottom portion of the source/drain opening; and
forming an isolation layer over the epitaxial layer.

20. The method of claim 19, wherein an air gap is formed vertically between the epitaxial seed layer and the isolation layer.
